(19) United States
(12) Patent Application Publication
(10) Pub. No.: US 2013/0293072 A1
(43) Pub. Date: Nov. 7, 2013

(54) TABLET AND ELECTRONIC MEDIA COVER PROTECTOR AND HANDLING APPARATUS

(71) Applicant: Antonio Sturniolo, San Diego, CA (US)

(72) Inventor: Antonio Sturniolo, San Diego, CA (US)

(21) Appl. No.: 13/661,032

(22) Filed: Oct. 25, 2012

Related U.S. Application Data
(60) Provisional application No. 61/552,314, filed on Oct. 27, 2011.

(51) Int. Cl. H05K 5/00; H05K 5/02

(52) U.S. Cl. CPC H05K 5/0004; H05K 5/02
USPC 312/138.1

(57) ABSTRACT

An improved cover and protector for handheld electronics and more specifically to a more dexterous tablet cover which allows for easier handling and positioning for easier user interface, and protection elements to avoid scratches, breaks from incidental contact, and accidental drops. The apparatus includes a front cover, a rear cover, and a removable handle affixed to the rear cover with lockable rotational adjustment.

### CROSS-REFERENCE TO RELATED APPLICATIONS

This application claims priority to currently pending U.S. patent application 61/552,314 filed Oct. 27, 2011 entitled Tablet and Electronic Media Cover, Protector and Handling Apparatus, the contents of which are incorporated herein by reference in its entirety.

### FIELD OF THE INVENTION

An improved cover and protector for handheld electronics and more specifically to a more dexterous tablet cover which allows for easier handling and positioning for easier user interface, and protection elements to avoid scratches, breaks from incidental contact, and accidental drops. The apparatus includes a front cover, a rear cover, and a removable handle affixed to the rear cover with lockable rotational adjustment.

### BACKGROUND

People are constantly on the go with their busy schedules, and typically are accompanied with a variety of tools for organize and conduct their daily lives including hand-held computers, cellular “smart” phones, electronic tablets, and other mobile devices. Some of these devices are large compared to the size of a person's hand, which requires dexterity to operate with both hands. Additionally, many of the latest devices currently available to consumers are expensive and easily susceptible to damage from scratching or dropping. As such, the present disclosure provides an apparatus to better hold, position, protect and use these tools by teaching an improved cover which may protect the these tools from scratching and damage, and facilitate an improved user interface while sitting down without access to a table, while walking, while running, or other activities difficult to perform while simultaneously handling an electronic device.

### SUMMARY OF THE INVENTION

The following presents a simplified summary in order to provide a basic understanding of some aspects of the claimed subject matter. This summary is not an extensive overview, and is not intended to identify key/critical elements or to delineate the scope of the claimed subject matter. Its purpose is to present some concepts in a simplified form as a prelude to the more detailed description that is presented later.

In one aspect of various exemplary embodiments, an apparatus for handling and protecting an electronic device is provided, the apparatus comprising: a front cover adapted for viewing a display screen of the electronic device, with the front cover constructed of at least a first material with soft durometer; a rear cover constructed of a material with hard durometer; a handle rotatably coupled to the rear cover; fastening means to join the rear cover to the front cover with the electronic device contained therebetween such that, when assembled, the position of the electronic device is fixed relative thereto; and an overall shape being formed similar to the electronic device to be protected.

In one aspect of various exemplary embodiments, an apparatus for handling and protecting an electronic device is provided, the apparatus comprising: a front cover and a rear cover formed to a shape similar to the electronic device when assembled therewith; the front cover permitting a user to view a display screen of the electronic device; a handle with an adjustable strap; the rear cover having a connection permitting rotatable attachment of the handle thereto; and fastening means joining the front cover to the rear cover with the electronic device contained therebetween.

In one aspect of various exemplary embodiments, an apparatus for handling and protecting an electronic device is provided, the apparatus comprising: means for protecting a front of the electronic device; means for protecting a rear of the electronic device; means for securing the rear protecting means to the electronic device; means for handling the electronic device; means for rotatably coupling the handling means to the rear protecting means; means for fastening the front protecting means to the rear protecting means with the electronic device contained therebetween; and means for restricting movement of the electronic device relative to the protecting means.

### BRIEF DESCRIPTION OF THE DRAWINGS

FIG. 1 is a front perspective view of an exemplary embodiment electronic device protector, with an exemplary front cover separated.

FIG. 2 is a front perspective view of another exemplary embodiment electronic device protector with a front cover removed.

FIG. 3 is a rear perspective view of FIG. 2 with an exemplary front cover.

FIG. 4 is a detail perspective view of an exemplary handle as shown in FIG. 3.

FIG. 5 is a detail rear perspective view of an exemplary handle assembled into an exemplary rear cover.

FIG. 6 is a detail perspective view of an exemplary handle as shown in FIG. 3 as removed from an exemplary rear cover.

FIG. 7 is an exploded rear view of yet another exemplary embodiment electronic device protector.

FIG. 8 is a rear view of FIG. 7 and a cross-section view thereof.

FIG. 9 is a detail view of FIG. 8.

### DETAILED DESCRIPTION

In the following detailed descriptions of various exemplary embodiments, reference is made to the accompanying drawings that form a part hereof, and in which is shown, by way of illustration, specific embodiments that may be practiced. It is to be understood that other embodiments may be utilized and structural changes may be made without departing from the scope of the present disclosure.

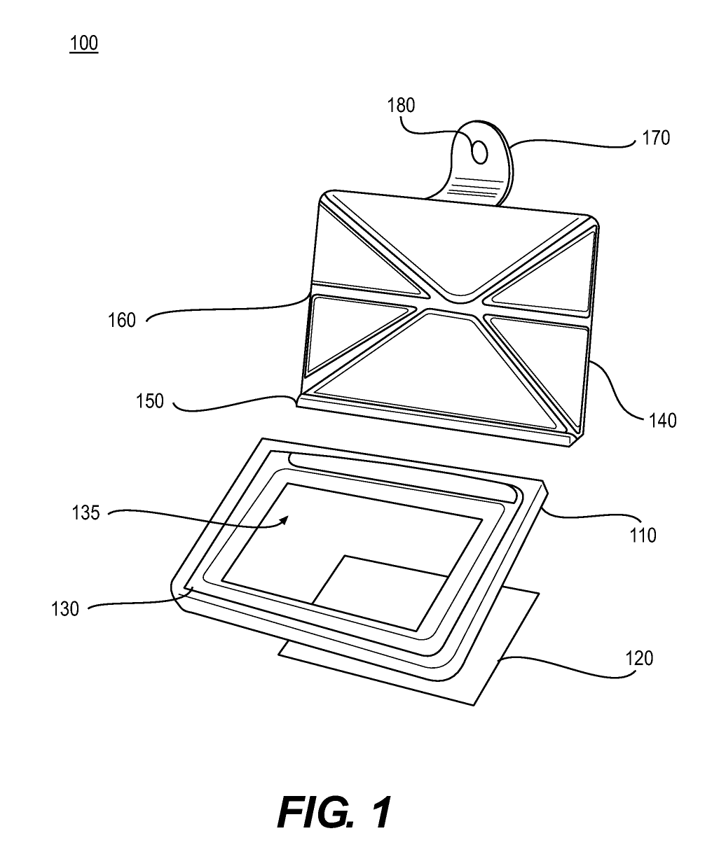

FIG. 1 illustrates an exemplary embodiment apparatus in exploded view form to more easily view the individual components. The electronic device is removed for clarity. The electronic device cover 110 may conform to the outside perimeter, rear plane, and front plane of the electronic device. In an embodiment, the electronic device cover 110 may be constructed of at least one durometer of rubber, plastic, silicone, neoprene, or other synthetic compound that can be formulated with different durometers. A soft durometer may be between 30 Shore OO and 50 Shore A, whereas a hard durometer may be between 51 Shore A and 75 Shore D.

In an embodiment, the perimeter 130 of the electronic device cover 110 may be constructed of a soft durometer material, whereas the back portion circumscribing the rear window 135 may be constructed of a hard durometer material. A soft durometer material for the perimeter 130 of the electronic device cover 110 may flex to allow insertion of the electronic device (not shown) into the front of the electronic device cover 110. The hard durometer material for the back portion of the electronic device cover 110 may give support to the rear cover 120.

In an embodiment, the rear cover 120 may nest within the electronic device cover 110, hence covering the rear window 135. The rear cover 120 may function as a rigid support for the handle (not shown). In another embodiment, the rear cover 120 may be incorporated as part of the electronic device cover 110, thereby eliminating the rear cover 120. It is contemplated that a common rear cover 120 can be used for simplicity of manufacture while creating electronic device covers 110 that are conformed to fit the various electronic device shapes.

FIG. 1 also illustrates the electronic device covering apparatus 100 with a removable cover 140. The removable cover 140 may be attached to the electronic device cover 110 or may be attached to the electronic device (not shown). Means with which to attach the removable cover 140 may be a magnet 150, pins, hinges, or other similar attachment means known to those skilled in the art. The removable cover 140 may comprise thin sections 160 about which a user may fold the removable cover in order to adjust viewing the electronic device display (not shown) upon placing the apparatus 100 onto a surface. Also, the apparatus 100 may comprise a flap 170 and snap 180 to close and secure the removable cover to the apparatus 100.

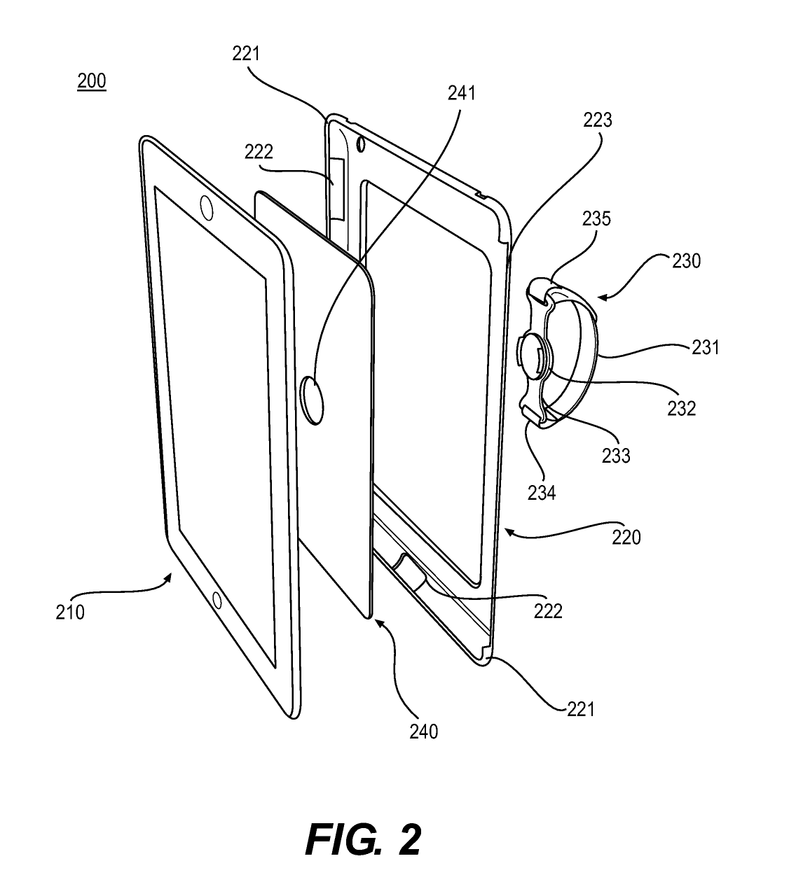

Turning now to FIG. 2, another embodiment of an apparatus 200 for protecting an electronic device 210 is shown. A removable cover is not shown for clarity. The front cover 220 may conform to the electronic device 210 and may at least partially envelop the rear of the electronic device 210. The front cover 220 may be adapted for viewing the display screen by covering only a small fraction of the front face of the electronic device 210. For example, the surface area of the front face of an 8 inch by 10 inch electronic device 210 may be 80 sq.in., but the surface area covered by the front cover 220 may be 3.56 sq.in. The surface area of the aforementioned example is computed by circumscribing a uniformly offset perimeter of approximately 0.1 inches on the face of the electronic device 210. Alternatively, the front cover 220 may be transparent to allow full coverage of the viewing screen. It is, however, contemplated that full coverage of the electronic device viewing screen by the front cover 220 may not be advantageous for a touch-screen interface.

As with the exemplary embodiment shown in FIG. 1, the front cover 220 in FIG. 2 may be constructed of at least one durometer of rubber, plastic, silicone, neoprene, or other synthetic compound that can be formulated with different durometers. A softer, low durometer material may be employed in the outer perimeter 221 of the front cover 220 to conform to the shape of the electronic device 210 and to protect the edges of the electronic device 210 from damage. Whereas the rear portion of the front cover 220 may employ a harder, high durometer material to support the rear cover 240. The rear cover 240 may nest within the front cover 220 where the rear cover 240 is contained between the front cover 220 and the electronic device 210 in order to restrict movement of the rear cover 240. Movement may be restricted through a friction fit. Additionally, operating apertures 222 are viewable in the front cover 220. These apertures 222 allow the user to access operations associated with the electronic device 210, such as universal serial bus (USB) ports, power adapter ports, microphone jacks, camera lenses, or various other ports.

FIG. 2 also illustrates an exemplary handle 230 that may be rotatably secured to the rear cover 240. Handle 230 may be comprised of a handle base 233, a handle pivot mechanism 232, a handle strap 231, a fixed strap end 234, and an adjustable strap end 235. The handle base 232 may employ at least one port through which the handle strap 231 may be passed, particularly for the adjustable strap end 235. The adjustable strap end 235 may be constructed with Velcro®, a watchband-type pin and hole combination, or other forms commonly known to those skilled in the art that yield length adjustment of the strap 231 to accommodate various hand sizes. For user comfort, the strap 231 may be constructed of fabric, rubber, or other soft, durable material known to those skilled in the art.

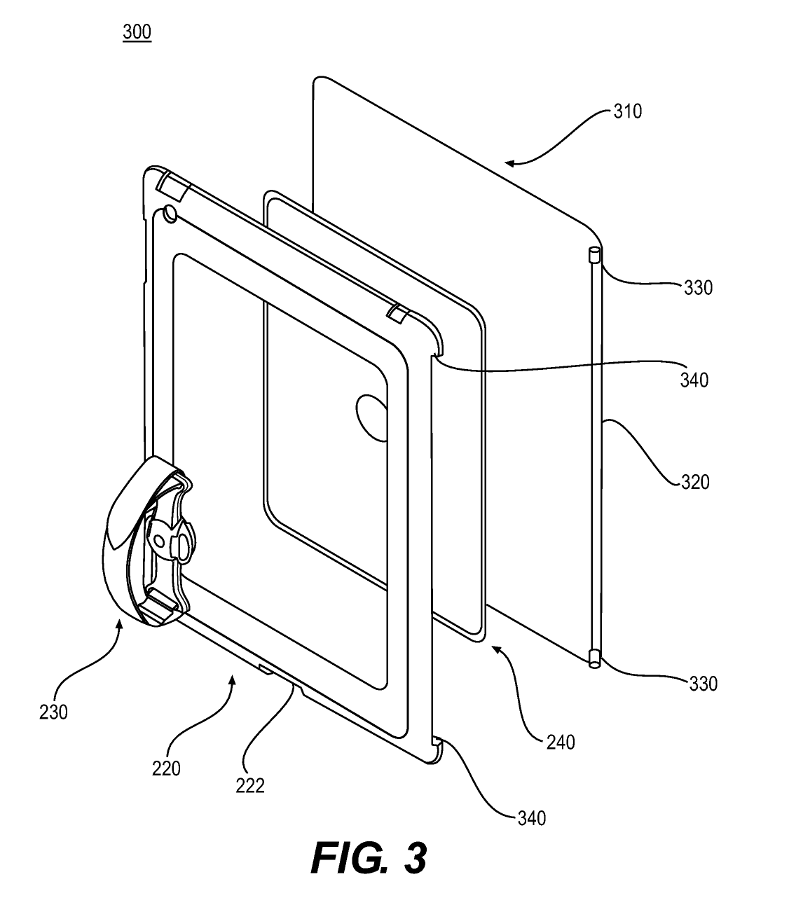

FIG. 3 is a rear perspective view of an exemplary embodiment apparatus 300 as shown in FIG. 2 yet with another exemplary front cover 310. An electronic device is not shown for clarity. The front cover 310 may be attached to the electronic device through a magnetic strip 320, or alternatively attached to the front cover 220 through a hinge mechanism as illustrated with pins 330 and sockets 340, or through other forms commonly known to those skilled in the art. Further still, the front cover 310 may be attached through a combination of magnets 320 and hinge mechanisms 330, 340. In this embodiment, the front cover 310 may be constructed partially or entirely of a rigid plastic with hard durometer.

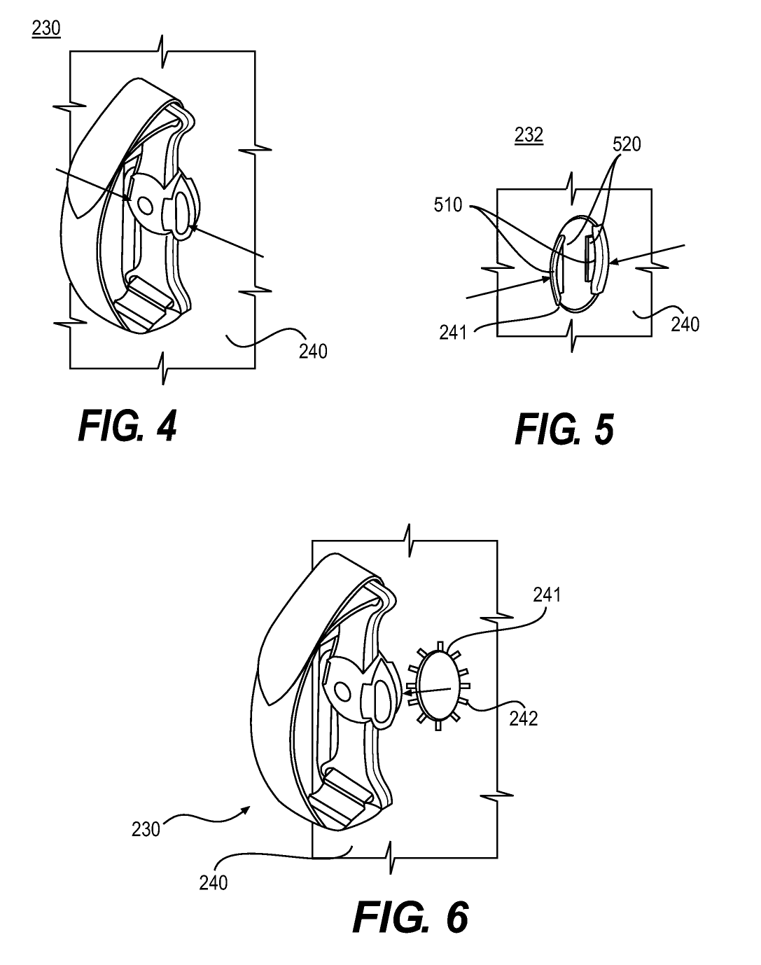

Turning now to FIGS. 4 through 6, a detail perspective view of an exemplary handle 230 and handle pivot mechanism 232 are shown. The handle pivot mechanism 232 requires no tools to operate, and is thus toolless. The handle pivot mechanism 232 may be operated by a user manually applying force on at least one side of the handle pivot mechanism 232 in the direction of the arrows. This applied force may elastically deform tangs 520 to disengage the semi-circular tabs 510 from the circular hole 241 in the rear cover 240. Alternatively, a compression spring (not shown) may be situated between the semi-circular tabs 510, or within the handle pivot mechanism 232, so that upon application of force, the compression spring (not shown) elastically deforms to allow the handle 230 to be disengaged from the rear cover 240 in the direction of the arrow as shown in FIG. 6. It is these semi-circular tabs 510, at least in this embodiment, that provide for rotation of the handle 230 about the hole 241.

In another embodiment, the handle 230 may be removed from circular hole 241 and replaced by a mounting bracket (not shown). Such a mounting bracket (not shown) would be useful for affixing the apparatus 100, 200, 300, 700 to a vehicle dashboard, a cup holder, a desk, or other frequently used locations where hands-free or single-hand operation is beneficial.

In yet another embodiment, as illustrated in FIG. 6, the rear cover 240 may have click-stops 242 disposed about the perimeter of the hole 241 at given angle intervals ranging from 15 to 30 to 45 to 60 to 75 to 90 to 105 to 120 to 135 to 150 to 165 and to 180 degrees. The semi-circular tabs 510 may have mating protrusions (not shown) that engage the click-stops 242 and provide rotational locking. Unlocking can be accomplished either by applying a rotational force upon the handle of sufficient quantity to surmount the radial force exerted by the tangs 520 or spring (not shown), or depressing the semi-circular tabs 510 in the direction of the arrows shown in FIG. 4 or FIG. 5, or by other means commonly known to those skilled in the art.

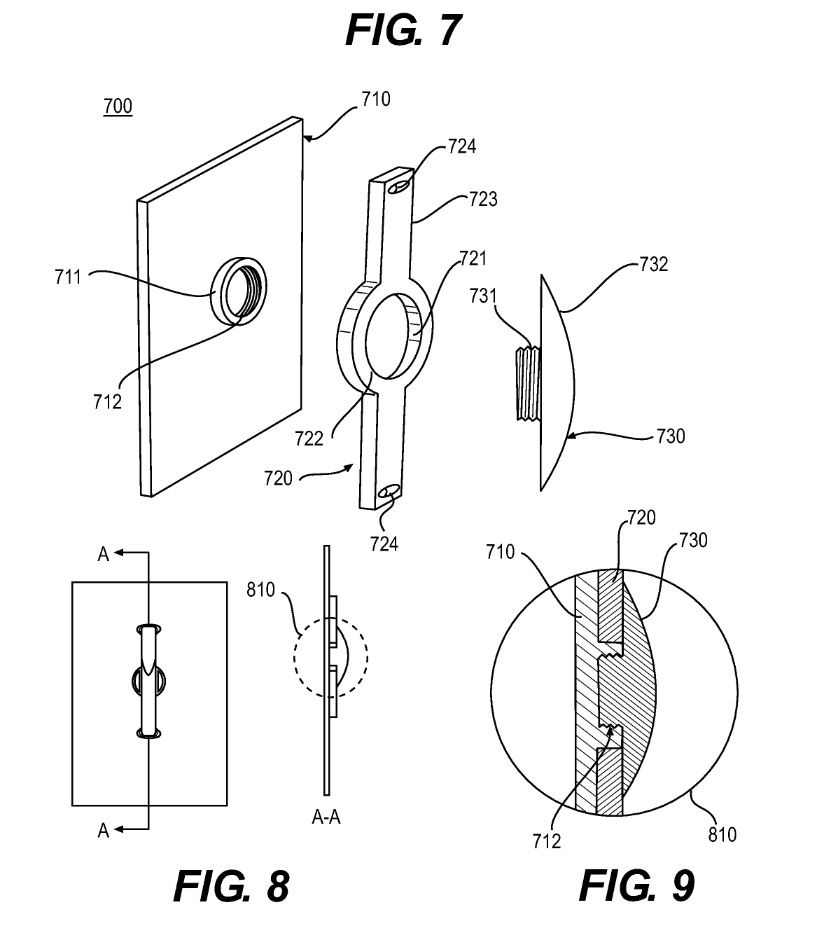

In still another embodiment, as illustrated in FIG. 7, an exploded rear view of an electronic device protector 700 is shown. The electronic device, front cover, handle strap, and removable front cover are not shown for clarity. Rear cover 710 may have a circular boss 711 protruding from the rear surface of the rear cover 710. The outer diameter of the circular boss 711 may rotatably interface with handle 720 at surface 721 to allow handle 720 to spin about the axis of the circular boss 711. The handle 720 may have arms 723 that radially extend from the center 722 of the handle 720. At least one slot 724 may be disposed in at least one arm 723 at or near the distal end of the arm 723 for inserting at least one end of the handle strap (not shown). The handle 720 is retained against the rear cover 710 by the handle pivot lock 730. Retaining means may be an outside thread 731 on the handle pivot lock and inside thread 711 on the inside diameter of the rear cover circular boss 711. Rotational locking may be achieved by a friction fit between the handle 720 and the handle pivot lock 730. The rear of handle pivot lock 730 may employ a partially hemispherical surface 732 to provide a comfortable fit with the palm of a user's hand.

FIG. 8 illustrates a rear view of FIG. 7 with cross-section view A-A thereof. Detail 810 is illustrated in FIG. 9 to illustrate a cross-section of the electronic device protector 700.

What has been described above includes examples of one or more embodiments. It is, of course, not possible to describe every conceivable combination of components or methodologies for purposes of describing the aforementioned embodiments, but one of ordinary skill in the art may recognize that many further combinations and permutations of various embodiments are possible. Accordingly, the described embodiments are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. An apparatus for protecting an electronic device, comprising:
a front cover adapted for viewing a display screen of the electronic device, with the front cover constructed of at least a first material with soft durometer;
a rear cover constructed of a material with hard durometer;
a handle rotatably coupled to the rear cover;
fastening means to join the rear cover to the front cover with the electronic device contained therebetween such that, when assembled, the position of the electronic device is fixed relative thereto; and
an overall shape being formed similar to the electronic device to be protected.

2. The apparatus of claim 1, wherein the front cover is constructed of a first material and a second material with durometer harder than the first material.

3. The apparatus of claim 1, wherein the front cover is secured to the electronic device through a friction fit.

4. The apparatus of claim 1, wherein the rear cover has a circular feature.

5. The apparatus of claim 1, wherein the handle rotates about the axis of the circular feature when mated therewith.

6. The apparatus of claim 1, wherein the handle rotatably locks at predetermined angles of orientation.

7. The apparatus of claim 1, wherein the handle comprises an adjustable strap to conform to a user's hand.

8. The apparatus of claim 1, wherein the handle can be removed from the rear cover.

9. The apparatus of claim 1, wherein the fastening means is a friction fit.

10. An apparatus for protecting an electronic device, comprising:
a front cover and a rear cover formed to a shape similar to the electronic device when assembled therewith;
the front cover permitting a user to view a display screen of the electronic device;
a handle with an adjustable strap;
the rear cover having a connection permitting rotatable attachment of the handle thereto; and
fastening means joining the front cover to the rear cover with the electronic device contained therebetween.

11. The apparatus of claim 10, wherein the rear cover is constructed of a hard durometer material.

12. The apparatus of claim 10, wherein the handle comprises a mechanism permitting toolless removal from the rear cover.

13. The apparatus of claim 10, wherein the connection on the rear cover is a hole for accepting the handle mechanism.

14. The apparatus of claim 10, wherein the connection on the rear cover threadably accepts an insert to secure the handle.

15. The apparatus of claim 10, wherein the fastening means is a friction fit.

16. The apparatus of claim 10, wherein the handle rotatably locks at predetermined angles of orientation.

17. An apparatus for protecting an electronic device, comprising:
means for protecting a front of the electronic device;
means for protecting a rear of the electronic device;
means for securing the rear protecting means to the electronic device;
means for handling the electronic device;
means for rotatably coupling the handling means to the rear protecting means;
means for fastening the front protecting means to the rear protecting means with the electronic device contained therebetween; and
means for restricting movement of the electronic device relative to the protecting means.

18. The apparatus of claim 17, wherein the front protecting means is constructed of at least a first material of soft durometer.

19. The apparatus of claim 17, wherein the rear protecting means is constructed of a hard durometer material.

20. The apparatus of claim 17, wherein the rotatable coupling means locks at predetermined angles of orientation.
